(19) United States
(12) Patent Application Publication
(10) Pub. No.: US 2008/0235557 A1
(43) Pub. Date: Sep. 25, 2008

(54) Semiconductor memory device

(75) Inventor: Saeng-Hwan Kim, Kyoungki-do (KR)

Correspondence Address: MCDERMOTT WILL & EMERY LLP, 600 13TH STREET, N.W., WASHINGTON, DC, 20005-3096, US

(73) Assignee: HYNIX SEMICONDUCTOR INC.

(21) Appl. No.: 12/003,278

(22) Filed: Dec. 21, 2007

(30) Foreign Application Priority Data
Mar. 22, 2007 (KR) 2007-0027924

(51) Int. Cl. H03M 13/05; G06F 11/10

(52) U.S. Cl. 714/755; 714/E11.034

(57) ABSTRACT

A semiconductor memory device includes: a plurality of error correction code (ECC) groups, each ECC group including plural data configured to be read from and written to the semiconductor memory device and plural parity data configured to correct an error of the plural data, wherein at least one of the ECC groups includes the plural data allocated in dispersed memory cells, not adjacent.

### CROSS-REFERENCE TO RELATED APPLICATIONS

The present invention claims priority of Korean patent application number 10-2007-0027924, filed on Mar. 22, 2007, which is incorporated by reference in its entirety.

### BACKGROUND OF THE INVENTION

The present invention relates to a semiconductor design technology, and more particularly, to a semiconductor memory device capable of correcting an error for itself based on an error correction code (ECC).

A conventional semiconductor memory device had to be repaired when a defect occurred because it was not able to recover by itself. However, for overcoming the above limitation, it attempts to overcome a defect by applying the ECC on a chip of the semiconductor memory device.

FIG. 1 is a diagram illustrating an arrangement of a bus line of a semiconductor memory device when a conventional ECC is applied.

Referring to FIG. 1, eight global data allocated from GIO0 to GIO7 and four parity data allocated from PA0 to PA3 form a first ECC group ECCGROUP_0, and eight global data allocated from GIO8 to GI15 and four parity data allocated from PA4 to PA7 form a second ECC group ECCGROUP_1.

The memory device performs an error correction operation by combining the global data and the parity data into each ECC group. In the memory device shown in FIG. 1, an error of eight global data is detected and recovered by using more allocated four parity data. That is, the memory device corrects the error by binding twelve bits to one ECC group.

Because each ECC group is limited to recover the error, in case of binding twelve bits to one ECC group, it can recover an error of only one bit among twelve bits of the ECC group. Therefore, if an error of two bits happens in one ECC group, it is difficult to recover the error of two bits of the ECC group for itself. Accordingly, the ECC group has to recover the error by using a column repair or a row repair of whole block.

For reference, a reference ‘BLSA’ means a bit line sense amplifier, a reference ‘SWD’ means a sub word-line driver block, a reference ‘CELL BLK’ means a cell block collecting the memory cell, a reference ‘X-DEC’ means an X-decoder, a reference ‘WL’ means a word-line, a reference ‘Y-DEC’ means an Y decoder, a reference ‘IOSA’ is an input/output sense amplifier, and a reference ‘WTDRV’ is a write driver.

FIG. 2 is a diagram showing a case that an error is not recovered by the ECC.

As shown, FIG. 2 illustrates a case of a bit line short between a second bit line bar BL2B and a third bit line BL3 because of a process badness. When the ECC group is allocated shown in FIG. 1, and the bit line short happens shown in FIG. 2, an error of two bits happens in one ECC group. Therefore, it is difficult to recover the error by an error correction using the ECC because of the bit line short.

In this case, the error correction can be performed by repair, not by the ECC.

Similarly, it has also a drawback that the ECC can not correct an error in case of contact badness of a sub word line because error of two or more bits happens in one ECC group.

### SUMMARY OF THE INVENTION

Embodiments of the present invention directed to providing a semiconductor memory device for extending capability of correcting badness.

In accordance with an aspect of the present invention, there is provided a semiconductor memory device, including: a plurality of error correction code (ECC) groups, each ECC group including plural data configured to be read from and written on the semiconductor memory device and plural parity data configured to correct an error of the plural data, wherein at least one of the ECC groups includes the plural data allocated in dispersed memory cells, not adjacent.

In accordance with another aspect of the present invention, there is provided a semiconductor memory device, including: a plurality of memory cells for storing plural data configured to be read from and written on the semiconductor memory device and plural parity data configured to correct an error of the data; and a plurality of sense amplifiers and drivers for inputting and outputting the data of the memory cells, wherein the data and the parity data form a plurality of error correction code (ECC) groups for performing an error correction, and at least one of the ECC groups includes the data allocated in dispersed memory cells, not adjacent.

### BRIEF DESCRIPTION OF THE DRAWINGS

FIG. 1 is a block diagram illustrating an arrangement of a bus line of a semiconductor memory device when a conventional ECC is applied;

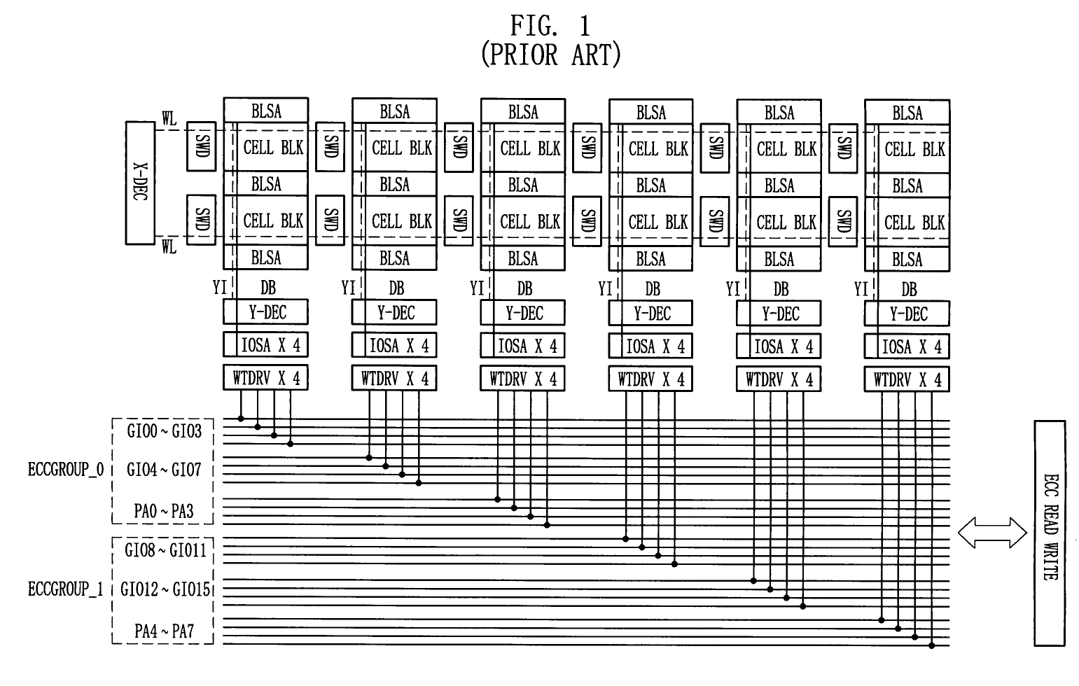

FIG. 2 is a diagram showing a case that an error is not recovered by the ECC;

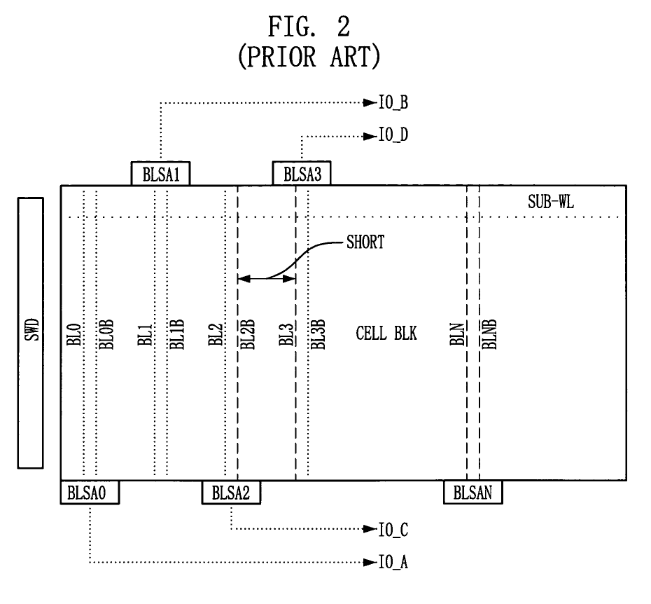

FIG. 3 is a block diagram of a semiconductor memory device using sixteen input/output terminals in accordance with a first embodiment of the present invention;

FIG. 4 is a block diagram of a semiconductor memory device using thirty-two input/output terminals in accordance with a second embodiment of the present invention;

FIGS. 5A and 5B are flowcharts showing encoding and decoding processes performed at an ECC group;

FIGS. 6A and 6B are block diagrams depicting a read/write path of a semiconductor memory device when an ECC is applied;

FIGS. 7A and 7B are diagrams illustrating the read/write path shown in FIG. 6 in detail; and

FIGS. 8A to 8C are detailed circuit diagrams of a syndrome decoder and an error corrector shown in FIG. 5B.

### DESCRIPTION OF SPECIFIC EMBODIMENTS

Hereinafter, preferred embodiments of the present invention will be set forth in detail with reference to the accompanying drawings so that those skilled in the art can easily carry out the invention. The present invention is not limited to the embodiments set forth below but may be implemented in various types, and these embodiments are provided only for full disclosure of the invention and for those skilled in the art to completely know the scope of the invention.

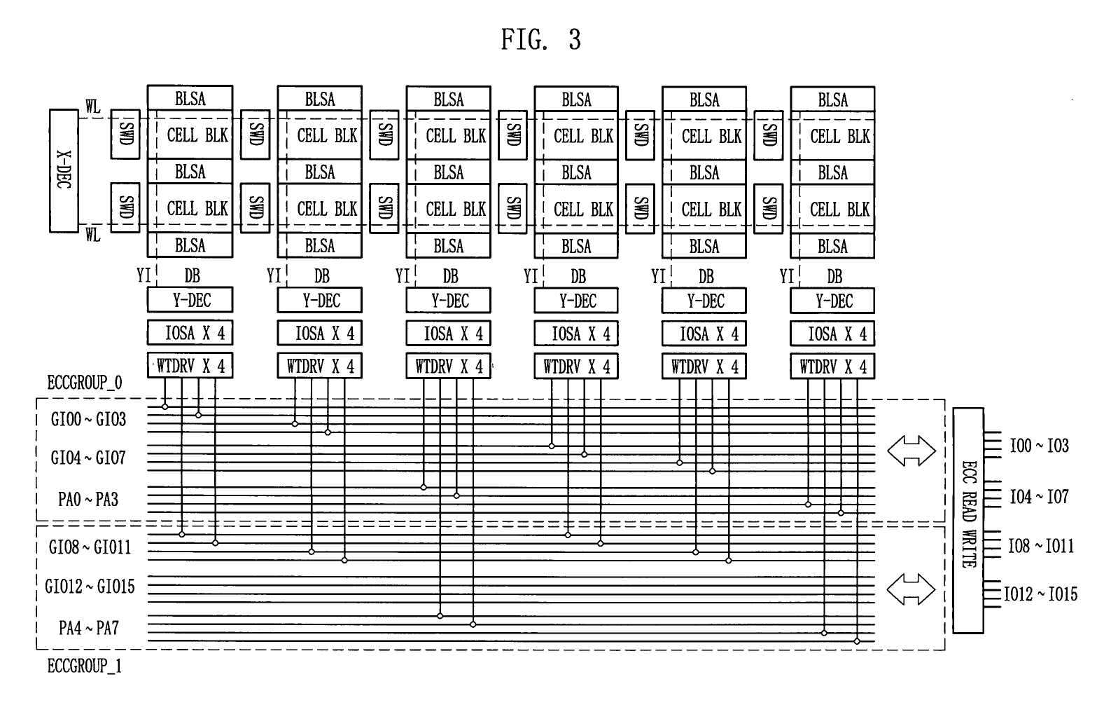

FIG. 3 is a block diagram of a semiconductor memory device using sixteen input/output terminals in accordance with a first embodiment of the present invention.

Referring to FIG. 3, the semiconductor memory device in accordance with the present invention includes a plurality of ECC groups ECCGROUP_0 and ECCGROUP_1 including a plurality of global data from GIO0 to GIO15 and a plurality of parity data from PA0 to PA7. The plurality of global data from GIO0 to GIO15 are read from or written on the semiconductor memory device and allocated at a global input/output (I/O) line. The plurality of parity data correct an error of the plurality of global data from GIO0 to GIO15 and are allocated at a parity line PA. At least one of the ECC groups includes the global data stored in memory cells which are dispersed, not adjacent.

Desirably, the plurality of parity data are stored in memory cells which are dispersed, not adjacent.

In the first ECC group ECCGROUP_0 shown in FIG. 3, a data near by a data allocated in GIO0 is allocated in the second ECC group ECCGROUP_1, not in the first ECC group ECCGROUP_0. That is, any of the global data GIO0 to GIO7 and the parity data PA0 to PA3 included in the first ECC group ECCGROUP_0 is not allocated near by each other. Likewise, any one of the global data GIO8 to GIO15 and the parity data PA4 to PA7 included in the second ECC group ECCGROUP_1 are not allocated near by each other.

If the data and the parity data are allocated dispersedly, the error of two bits by a bit line short is allocated separately one by one in the first ECC group ECCGROUP_0 and the second ECC group ECCGROUP_1 even if the bit line short happens. That is, it is difficult to correct the error based on error of two bits in one ECC group in the Prior Art. However, if the ECC group is allocated according to the present invention, it has advantage of correcting an error by ECC group itself and not needing a repair because the error are dispersed one by one in the two ECC groups.

A main idea of the present invention is a dispersing an error generated in the semiconductor memory device to the different ECC groups from each other. Therefore, if the error beyond capable of correcting the error occurs in a specific part of the semiconductor memory device, the error can be separately allocated in the different ECC groups from each other so as to be corrected in the ECC group itself.

If the global data and the parity data of all the ECC groups are allocated separately as same as described in drawings, it is possible to repair the most error. However, in accordance with a design technology, it is possible to allocate separately the data and the parity data of a specific one of various ECC groups or allocate the parity data based on the conventional invention and allocate separately the data only.

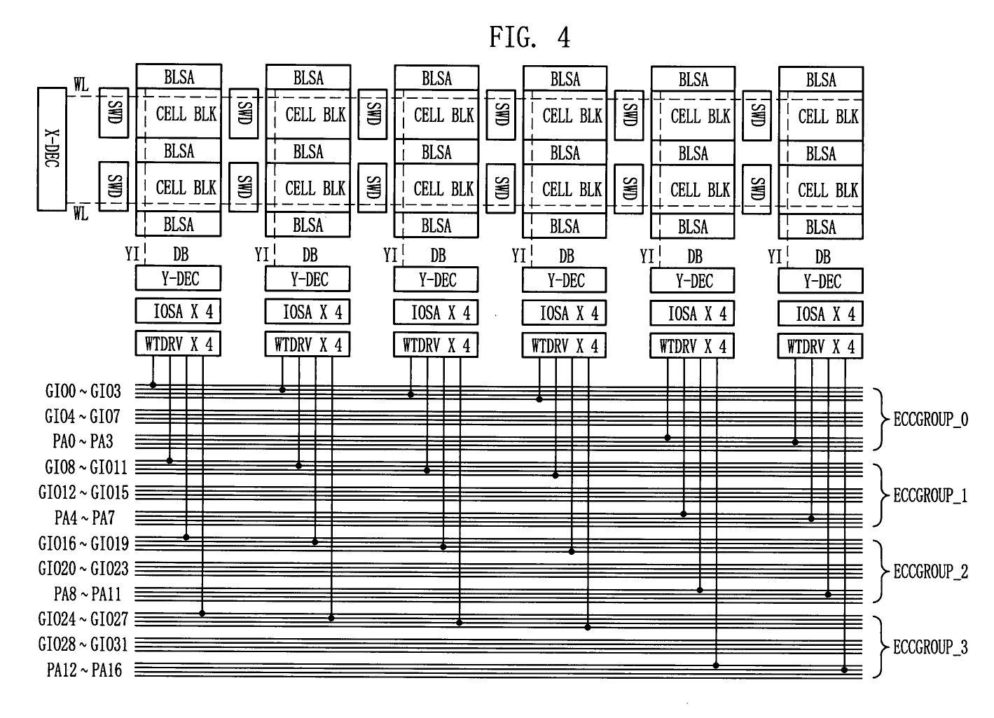

FIG. 4 is a block diagram of a semiconductor memory device using thirty-two input/output terminals in accordance with a second embodiment of the present invention.

FIG. 4 illustrates a case of forming four ECC groups, i.e., first to fourth ECC groups ECCGROUP_0 to ECCGROUP_3, using thirty-two inputs and outputs, and illustrates a half of twelve bits forming ECC groups, i.e., six bits. In a case of using thirty two inputs and outputs as shown in FIG. 4, it is possible to allocate separately global data and parity data in the ECC groups more than a case of using sixteen inputs and outputs shown in FIG. 3.

That is, In FIG. 4, not only the global data and the parity data included in the same ECC group are not allocated adjacently on the bit line, but also the global data and the parity data included in the same ECC groups are not allocated to the same sub word line driver block SWD. Therefore, if an error by a sub word line contact badness happens, it is possible for the ECC group itself to correct the error.

As shown, the global data and the parity data allocated in an input/output sense amplifier block IOSA×4 and a write driver block WTDRV×4 grouped by one block are allocated respectively in the different ECC groups. For example, the data inputted and outputted through the input/output sense amplifier block IOSA×4 and the write driver block WTDRV×4 are allocated separately in the first to fourth ECC groups ECCGROUP_0 to ECCGROUP_3. In this case, if the badness happens in the input/output sense amplifier block IOSA×4 and the write driver block WTDRV×4, a recovering ability of the ECC group itself improves more than the conventional invention.

There are various kinds of method to allocate separately the global data and the parity data included in the same ECC group. If the global data and the parity data included in the same ECC group are allocated in a different word line from each other, the word line contact badness can be recovered in the ECC group itself.

It is described to allocate the global data and the parity data of the ECC group in accordance with the present invention. It will be described below how the error correction is performed in the ECC group. Though the error correction performed in the ECC group has various kinds of methods, one of the methods is described with reference to the drawings. Although the ECC group performs the error correction in any method, it is possible to improve the error correction ability of the ECC group by the separate allocation as described above.

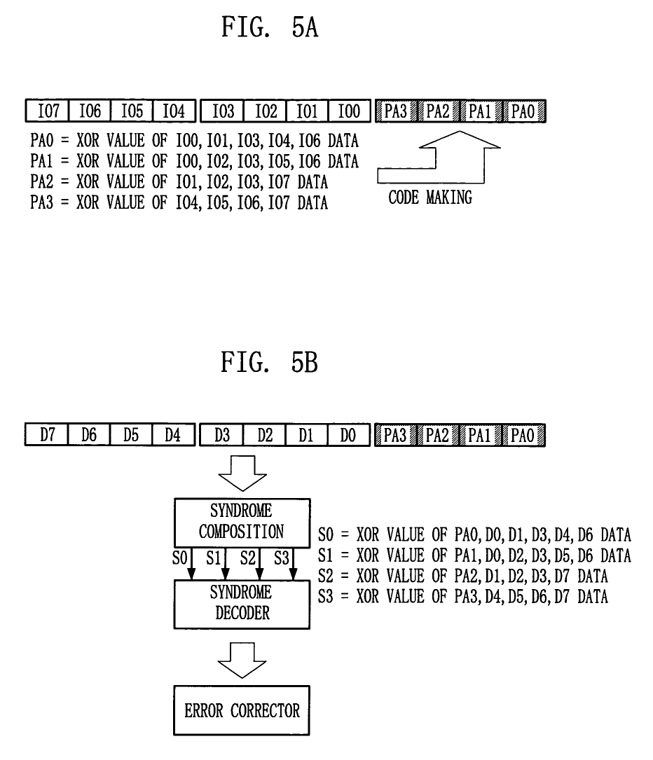

FIGS. 5A and 5B are flowcharts showing encoding and decoding processes performed at the ECC group.

FIG. 5A illustrates an encoding process and FIG. 5B illustrates a decoding process. A total 12 bits having the 8-bit global data and the 4-bit parity data form one ECC group.

The encoding process generates parity data PA0 to PA3 using input/output (I/O) data IO0 to IO7. This process is called as a hamming encoding. The parity data PA0 to PA3 is generated by an XOR operation of the I/O data IO0 to IO7, and FIG. 5A illustrates that a respective parity data PA0 to PA3 is generated by a certain XOR operation.

The decoding process corrects an error of data D0 to D7 by using the generated parity data PA0 to PA3. First of all, the decoding process generates syndrome data S0, S1, S2, S3 through a process of a syndrome composition. The respective syndrome data S0 to S3 generated by an XOR operation of the data D0 to D7 and the parity data PA0 to PA3 as shown in FIG. 5B. At this process, a value of the syndrome data S0 to S3 fluctuates according to whether the error exists or not. It is possible to know a position of the error according to the syndrome data S0 to S3 and correct the error by using a syndrome decoder and an error corrector. The syndrome decoder and the error corrector will be described later.

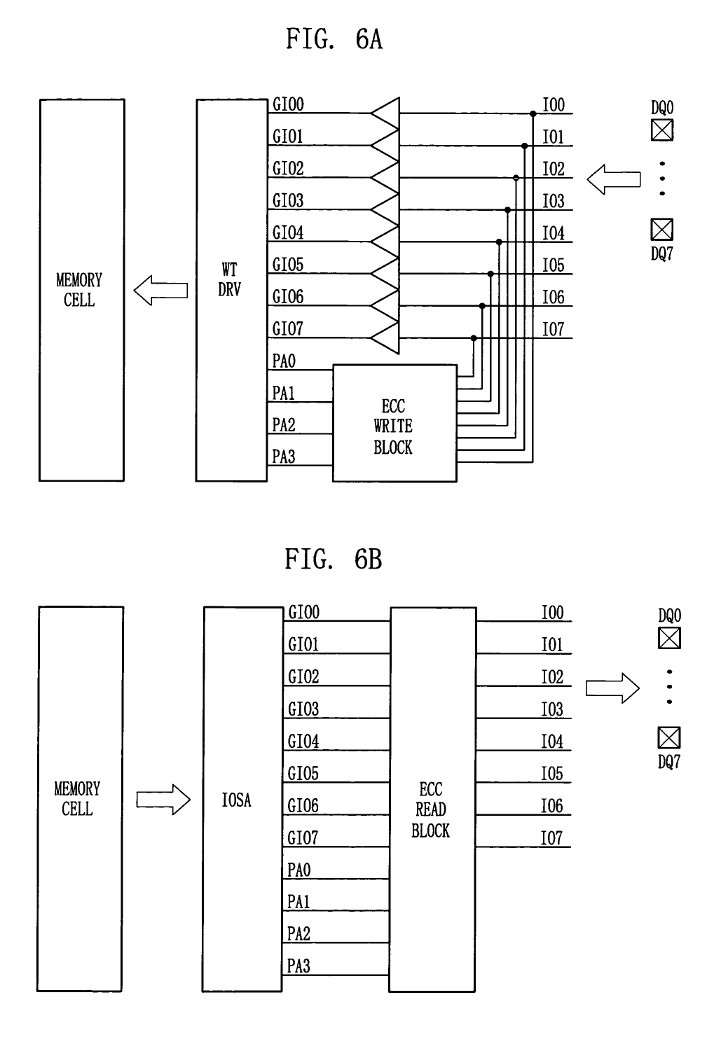

FIGS. 6A and 6B are block diagrams depicting a read/write path of the semiconductor memory device when the ECC is applied.

FIG. 6A is a diagram illustrating a write path. Referring to FIG. 6A, an ECC write block generates the parity data PA0 to PA3 based on the I/O data IO0 to IO7 inputted from DQ pins DQ0 to DQ7. The write driver WTDRV writes the global data GIO0 to GIO7 and the parity data PA0 to PA3 to the memory cell.

FIG. 6B is a diagram illustrating a read path. Referring to FIG. 6B, the input and output sense amplifier IOSA reads out the global data GIO0 to GIO7 and the parity data PA0 to PA3 stored in the memory cell. An ECC read block corrects an error, and finally outputs the I/O data IO0 to IO7 through DQ pins DQ0 to DQ7. For reference, the ECC read block performs the decoding process according to the flowchart of FIG. 5B.

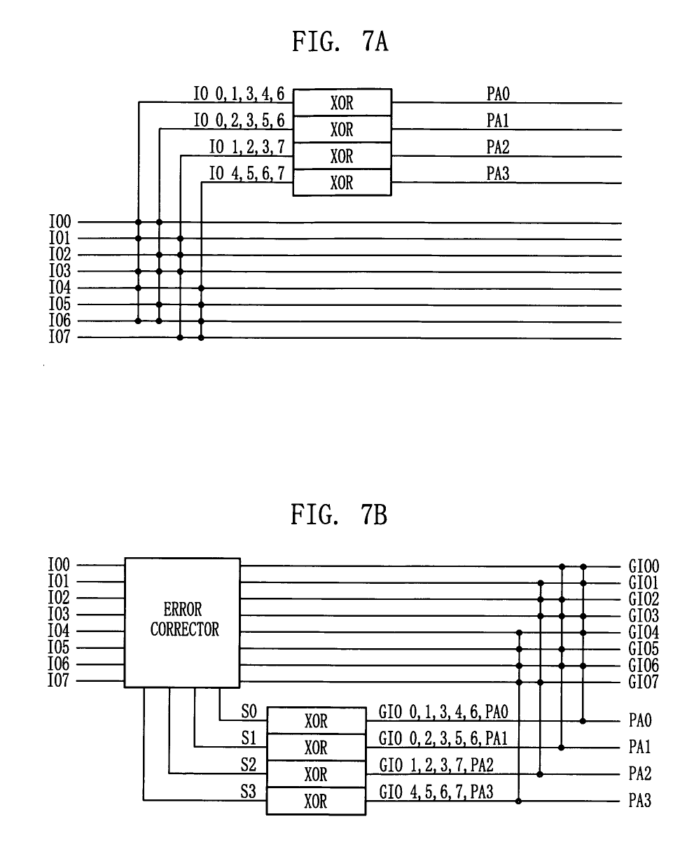

FIGS. 7A and 7B are diagrams illustrating the read/write path shown in FIG. 6 in detail.

FIG. 7A is a diagram illustrating the write path. Herein, a write operation is performed from left to right. Describing briefly, the ECC write block generates the parity data PA0 to PA3 based on the I/O data IO0 to IO7 and writes the parity data PA0 to PA3 and the data 100 to IO7 to the memory cell.

FIG. 7B is a diagram illustrating the read path. Herein, a read operation is performed from right to left. Describing briefly, the input and output sense amplifier IOSA generates the syndrome data S0 to S3 based on the global data GIO0 to GIO7 and the parity data PA0 to PA3 stored in the memory cell, and the error corrector outputs the I/O data IO0 to IO7 to the DQ pins by correcting the error.

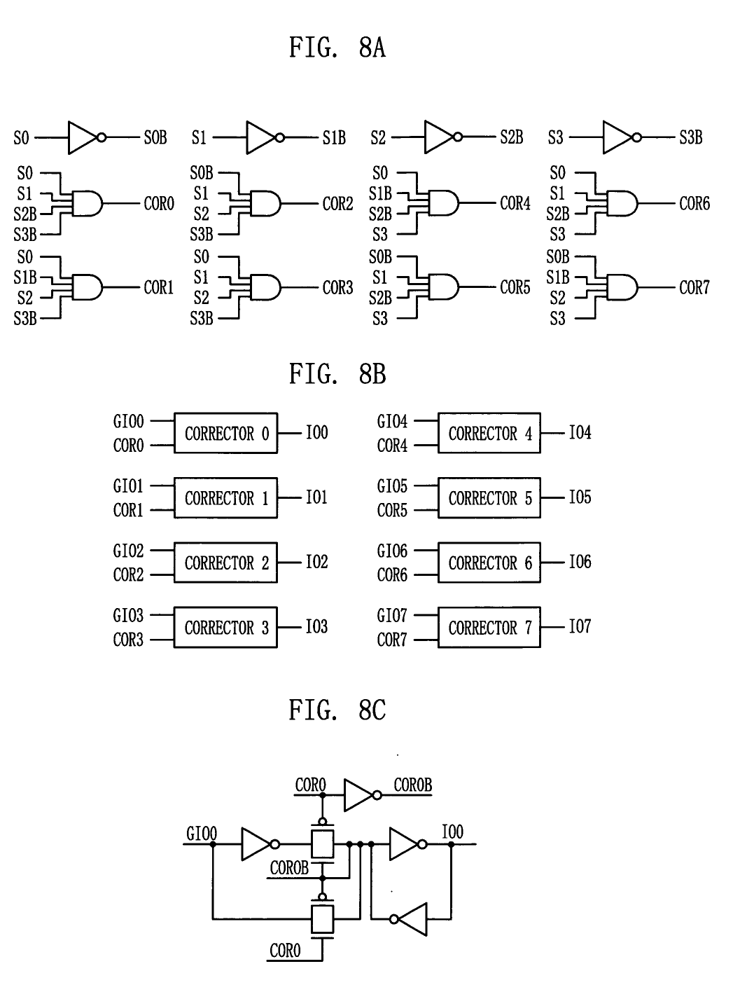

FIGS. 8A to 8C are detailed circuit diagrams of the syndrome decoder and the error corrector shown in FIG. 5B.

FIG. 8A is a diagram of illustrating the syndrome decoder. As shown, the syndrome decoder carries out an AND operation on the syndrome data S0 to S3 and an inverse data of the syndrome data S0B to S3B, and generates corrected signals COR0 to COR7.

FIG. 8B illustrates the error corrector including first to eight error correcting units CORRECTOR0 to CORRECTOR7. The first to eight error correcting units CORRECTOR0 to CORRECTOR7 output the I/O data IO0 to IO7 by correcting the global data GIO0 to GIO7 based on corrected signals COR0 to COR7 generated at the syndrome decoder.

FIG. 8C is a diagram illustrating the first error correcting unit CORRECTOR0 in detail. The error correcting unit CORRECTOR0 outputs the first I/O data IO0 by inverting or not inverting the first global data GIO0 according to a logic level of the corrected signal COR0. As well known by the people, for it is possible to correct an error of a data by just inverting the data in case of a binary data.

While the present invention has been described with respect to the specific embodiments, it will be apparent to those skilled in the art that various transpositions, changes, and modifications may be made without departing from the spirit and scope of the invention as defined in the following claims.

What is claimed is:

1. A semiconductor memory device, comprising:
a plurality of error correction code (ECC) groups, each ECC group including plural data configured to be read from and written to the semiconductor memory device and plural parity data configured to correct an error of the plural data,
wherein at least one of the ECC groups includes the plural data allocated in dispersed memory cells, not adjacent.

2. The semiconductor memory device as recited in claim 1, wherein the plural parity data in the same ECC group are stored in the dispersed memory cells, not adjacent.

3. The semiconductor memory device as recited in claim 1, wherein each of dispersed memory cells belongs to bit lines which are allocated not adjacent to each other.

4. The semiconductor memory device as recited in claim 1, wherein the dispersed memory cells belong to different sub word line driver blocks from each other.

5. The semiconductor memory device as recited in claim 1, wherein the dispersed memory cells belong to different word lines from each other.

6. The semiconductor memory device as recited in claim 1, wherein the ECC group includes the global data of 8 bits and the parity data of 4 bits.

7. A semiconductor memory device, comprising:
a plurality of memory cells for storing plural data configured to be read from and written to the semiconductor memory device and plural parity data configured to correct an error of the data; and
a plurality of sense amplifiers and drivers for inputting and outputting the data of the memory cells,
wherein the data and the parity data form a plurality of error correction code (ECC) groups for performing an error correction, and at least one of the ECC groups includes the data allocated in dispersed memory cells, not adjacent.

8. The semiconductor memory device as recited in claim 7, wherein the plural parity data in the same ECC group are stored in the dispersed memory cells, not adjacent.

9. The semiconductor memory device as recited in claim 7, wherein each of dispersed memory cells belongs to bit lines which are allocated not adjacent to each other.

10. The semiconductor memory device as recited in claim 7, wherein the dispersed memory cells belong to different sub word line driver blocks from each other.

11. The semiconductor memory device as recited in claim 7, wherein the dispersed memory cells belong to different word lines from each other.

12. The semiconductor memory device as recited in claim 7, wherein the ECC group includes the global data of 8 bits and the parity data of 4 bits.
